(19) United States
(12) Patent Application Publication
(10) Pub. No.: US 2019/0333962 A1
(43) Pub. Date: Oct. 31, 2019

(54) IMAGE SENSORS AND FORMING METHODS OF THE SAME

(71) Applicant: HuaiAn Imaging Device Manufacturer Corporation, Huaian (CN)

(72) Inventors: Yanqiang He, Huaian (CN); Tsungde Lin, Huaian (CN); Jente Huang, Huaian (CN); Xiaoming Li, Huaian (CN); Yukun He, Huaian (CN)

(73) Assignee: HuaiAn Imaging Device Manufacturer Corporation, Huaian (CN)

(21) Appl. No.: 16/383,586

(22) Filed: Apr. 13, 2019

(30) Foreign Application Priority Data
Apr. 25, 2018 (CN) 201810379304.1

(51) Int. Cl. H01L 27/146

(52) U.S. Cl. CPC H01L 27/14698; H01L 27/14643; H01L 27/14689; H01L 27/1463; H01L 27/1461

(57) ABSTRACT

An image sensor and a method of forming the same, wherein the forming method includes: providing a substrate including a protective layer, the substrate comprising a photoelectric region; forming a photo-doped region in the photoelectric region; doping improvement ions at an interface between the photoelectric region and the protective layer, wherein the improvement ions are combined with a dangling bond at the interface. The method may reduce dark currents of the image sensor.

### CLAIM OF PRIORITY

This application claims priority to Chinese Application number 201810379304.1, filed on Apr. 25, 2018, entitled “IMAGE SENSORS AND METHODS OF FORMING THE SAME”, the content of which is incorporated herein by reference in its entirety.

### TECHNICAL FIELD

The present disclosure relates to the field of semiconductor manufacturing and photoelectric imaging technology, and particularly to an image sensor and a method of forming the same.

### BACKGROUND

An image sensor is a semiconductor device that converts an optical image signal into an electrical signal. Products that use image sensors as key components have become the focus of current and future industry attention, attracting many manufacturers to invest. According to product categories, image sensor products are mainly divided into Charge-coupled Device Image Sensor (CCD image sensor) and Complementary Metal Oxide Semiconductor Image Sensor (CMOS Image Sensor). The CMOS image sensor is a kind of rapidly developing solid-state image sensor. Since the image sensor portion and the control circuit portion of the CMOS image sensor are integrated in the same chip, the CMOS image sensor is small in size, low in power consumption, and low in cost. Compare to the series CCD image sensor, CMOS image sensor has advantages and is easier to popularize.

However, the existing image sensor has a large dark current. The dark current refers to the inverse direct current generated when the device is in the state of reverse bias without incident light. When the image sensor is working, the dark current will penetrate into the signal current, causing signal interference, resulting in degradation of the image sensor performance.

### SUMMARY

The technical problem to be solved by the present disclosure is to provide an image sensor and a method of forming the same to reduce the dark current of the image sensor. In order to solve the above technical problem, the present disclosure provides a method of forming an image sensor.

The method includes: providing a substrate, wherein the substrate includes a protective layer over a surface of the substrate, and a photoelectric region; forming a photoelectric-doped region in the photoelectric region; and doping improvement ions at an interface between the photoelectric region of the substrate and the protective layer, wherein the improvement ions are combined with a dangling bond at the interface.

In some embodiments of the present disclosure, the improvement ions include fluoride ions.

In some embodiments of the present disclosure the doping of the improvement ions at the interface includes: forming an improvement layer on the corresponding protective layer of the photoelectric region, wherein the improvement layer includes the improvement ions; and performing anneal to diffuse the improvement ions to the interface between the protective layer and the photoelectric region.

In some embodiments of the present disclosure, the method of doping the improvement ions at the interface includes: forming a second gate structure on a surface of a portion of the photoelectric region; forming a first dielectric layer over the second gate structure, wherein a thickness of the first dielectric layer substantially equals to that of the gate structure; removing the second gate structure to form an opening in the first dielectric layer, the opening exposing the protective layer; forming the improvement layer at the bottom of the opening, the improvement layer including the improvement ions; and performing the anneal to diffuse the improvement ions to the interface.

In some embodiments of the present disclosure, a material of the improvement layer includes fluorine-doped silicon oxide, and the improvement ions include fluoride ions.

In some embodiments of the present disclosure, the forming of the improvement layer includes performing a solid source doping process.

In some embodiments of the present disclosure, an atomic percentage concentration of the improvement ions in the improvement layer is 1% or more and 10% or less.

In some embodiments of the present disclosure, the anneal includes a rapid anneal having an annealing temperature of 400 degrees Celsius or more and 700 degrees Celsius or less, and an annealing time of 30 seconds or more and 120 seconds or less.

In some embodiments of the present disclosure, the method further includes, before forming the first dielectric layer: forming a first gate structure on the surface of the substrate; and forming a floating diffusion region in the substrate at one side of the first gate structure, wherein the floating diffusion region and the photoelectric-doped region are respectively located on opposite sides of the first gate structure, and the floating diffusion region includes third dopant ions, wherein the third dopant ions are of a same doping type as second dopant ions, and the second dopant ions are located in the photoelectric-doped region.

In some embodiments of the present disclosure, the method further includes, after forming the improvement layer: forming a second dielectric film in the opening and a surface of the first dielectric layer, the second dielectric film filling the opening; and flattening the second dielectric film until a top surface of the first gate structure is exposed, and the second dielectric layer is formed within the opening.

In some embodiments of the present disclosure, the anneal is performed after the second dielectric film is formed and before the second dielectric layer is formed.

In some embodiments of the present disclosure, the method further includes, forming an isolation region between the photoelectric-doped region and the protective layer, and forming the isolation region by performing an ion implantation process on the substrate, wherein a conductivity type of dopant ions in the isolation region is opposite to that of dopant ions in the photoelectric-doped region.

In some embodiments of the present disclosure, the substrate includes an isolation structure, and a doped isolation region between the isolation structure and the substrate, wherein the doping isolation region is formed by performing an ion implantation process on the substrate, and a conductivity type of dopant ions in the doped isolation region is opposite to that of dopant ions in the photoelectric-doped region.

In some embodiments of the present disclosure, there is provided an image sensor, which includes: a substrate including a protective layer over a surface of the substrate, and a photoelectric region; a photoelectric-doped region located within the photoelectric region; at least a layer of improvement ions located at an interface between the photoelectric region and the protective layer, wherein the improvement ions are combined with a dangling bond at the interface.

In some embodiments of the present disclosure, the improvement ions include fluoride ions.

In some embodiments of the present disclosure, the image sensor further includes an improvement layer, located on a corresponding protective layer of the photoelectric region, wherein the improvement layer includes the improvement ions.

In some embodiments of the present disclosure, a material of the improvement layer includes fluorine-doped silicon oxide, and the improvement ions include fluoride ions.

In some embodiments of the present disclosure, the photoelectric-doped region includes second dopant ions; and the substrate further include a well region, including first dopant ions, wherein a conductivity type of the first dopant ions is opposite to that of the second dopant ions.

In some embodiments of the present disclosure, the image sensor further includes an isolation region between the photoelectric-doped region and the protective layer, wherein a conductivity type of dopant ions in the isolation region is opposite to that of dopant ions in the photoelectric-doped region.

In some embodiments of the present disclosure, the substrate includes an isolation structure; and a doped isolation region located between the isolation structure and the substrate, wherein a conductivity type of the dopant ions in the doped isolation region is opposite to that of dopant ions in the photoelectric-doped region.

Compared with the prior art, the technical solution of the embodiment of the present disclosure has the following benefits:

In the method of forming an image sensor provided by the technical solution of the present disclosure, the protective layer is formed to protect the top surface of the substrate in the process of forming the photoelectric-doped region. After forming the photoelectric-doped region, doping ions are doped at the interface between the substrate of photo-electric region and the protective layer, and the doping ions may be bonded to dangling bonds at the interface, therefore, the doping ions may repair the defect at the interface between the substrate of the photo-electric region and the protective layer, and thus reducing the dark current between the substrate of the photo-electric region and the protective layer.

Further, in the process of doping the improvement ions at the interface between the substrate of photo-electric region and the protective layer, a second gate structure is formed on a portion of the surface of the substrate of photoelectric region, and the second gate structure is formed to define the position of the subsequent improvement layer, since the second gate structure is separated from the subsequent first gate structure, the improvement layer does not contact with the first gate structure, so that the improvement ions in the improvement layer do not affect the performance of the first gate structure. Moreover, the improvement layer covers a portion of the protective layer of photoelectric region, and is subsequently treated by anneal to diffuse the improvement ions to the interface between the substrate of photoelectric region and the protective layer. In summary, the method makes it possible to reduce the dark current at the interface between the substrate of photoelectric region and the protective layer, while the improvement ions do not affect the performance of the first gate structure, and the process is simple.

Further, performing the annealing process makes it possible that during the process of improvement ions entering the interface between the substrate of photoelectric region and the protective layer, the annealing process has less damage to the protective layer and the substrate, which is advantageous for further reducing dark current.

Further, the forming method further includes forming an isolation region surrounding the isolation structure and the top of the photoelectric-doped region, wherein the conductivity type of the fourth dopant ions in the isolation region is opposite to that of the second dopant ions, and thus, the isolation region may further reduce dark current.

### BRIEF DESCRIPTION OF THE DRAWINGS

The present disclosure is further described in terms of exemplary embodiments. The foregoing and other aspects of embodiments of present disclosure are made more evident in the following detail description, when read in conjunction with the attached drawing figures.

FIG. 1 is a schematic structural view of an image sensor, according to embodiments of the present disclosure; and

FIG. 2 to FIG. 11 are structural diagrams showing the steps of an embodiment of a method for forming an image sensor according to embodiments of the present disclosure.

### DETAILED DESCRIPTION

In order to provide a thorough understanding of the relevant disclosure to those skilled in the art, the specific details of the disclosure are set forth by embodiments in following detailed description. However, the disclosure of the present application should be understood to be consistent with the scope of the claims, and not limited to the specific details of the disclosure. For example, various modifications of the embodiments disclosed in the present disclosure will be apparent to those skilled in the art; and without departing from the spirit and scope of the application, those skilled in the art may apply the general principles defined here to other embodiments and applications. For example, if the details are not disclosed below, those skilled in the art may also make the application without knowing the details. On the other hand, in order to avoid unnecessarily obscuring the contents of the present application, the present application summarizes the known methods, processes, materials, devices, etc., but does not describe them in detail.

The terms used in the present application is for the purpose of describing the particular exemplary embodiments, nut not a limitation to the application. For example, unless the context clearly dictates otherwise, a singular description of an element (such as “a”, “an” and/or the like) may also include a plurality of the elements. The term “including” and/or “comprising” as used in this application refers to the concept of openness. For example, A includes/comprises B only indicate the existence of B features in A, but does not exclude the possibility that other elements (such as C) exist or be added in A. In the present application, the term “and/or” includes any and all combinations of one or more of the associated listed items.

In the present application, the same reference numerals indicate similar structures in the several views of the drawings. Those of ordinary skill in the art will understand that these embodiments are non-limiting and exemplary embodiments. The drawings are only for the purpose of illustration and description, and are not intended to limit the scope of the application. The intent of the invention in this application may also be completed by other embodiments. It should be understood that the drawings are not drawn to scale.

The flowcharts used in this application illustrate the operational steps of process of some embodiments of the present application. It should be clearly understood that the process steps of the flowcharts may be implemented out of the order. Instead, operations may be implemented in reverse order or simultaneously. In addition, one or more other operations may be added to the flowchart. One or more actions may be removed from the flowchart.

It should be understood that when an element is referred to as “connected” or “coupled” to another element, it may be directly connected or coupled to the other element, or an intermediate element may be present. Similarly, when an element such as a layer, a region or a substrate is referred to as being “on” another element, it may be directly on the other element or the intermediate element may be present. In contrast, the term “directly” means that there are no intermediate elements.

Further, the embodiments in the detailed description will be described using a sectional view as preferred exemplary drawings of the inventive concept. Thus, the shape of the exemplary drawings may be changed depending on manufacturing techniques and/or permissible errors. Thus, embodiments of the inventive concept are not limited to the specific shapes shown in the exemplary drawings, but may include other shapes that may be produced in accordance with the manufacturing process. The regions illustrated in the figures have general attributes and are used to illustrate the particular shapes of the elements. Therefore, this should not be construed as limiting the scope of the inventive concept.

It should also be understood that although the terms first, second, third, etc. may be used herein to describe various elements, these elements should not be limited by these terms. These terms are only used to distinguish one element from another. Thus, a first element in some embodiments could be termed a second element in other embodiments without departing from the teachings of the invention. The same reference numbers or the same reference numerals will be used throughout the specification.

Further, the exemplary embodiments are described by referring to the sectional view and/or plan. Thus, differences from the shapes illustrated may be foreseeable due to, for example, manufacturing techniques and/or tolerances. Therefore, the exemplary embodiments should not be construed as limited to the shapes of the regions illustrated herein, but should include variations in the shapes resulting from, for example, manufacturing. For example, an etched region illustrated as a rectangle will typically have rounded or curved features. The regions illustrated in the figures are, therefore, not intended to illustrate the actual shape of the regions of the device or the scope of the exemplary embodiments.

As described in the background of the invention, the dark current of the image sensor is severe.

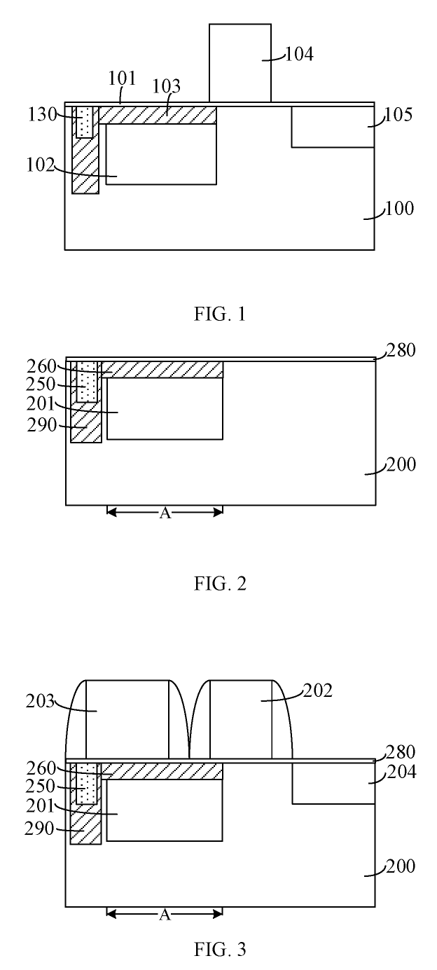

FIG. 1 is a schematic structural view of an image sensor. The image sensor may include a substrate 100, a protective layer 101, a photoelectric-doped region 102, an isolation region 103, a gate structure 104, a floating diffusion region 105, and an isolation structure 130.

Referring to FIG. 1, the substrate 100 includes a well region (not shown in the figure). The well region includes a kind of first dopant ions and a portion of the well region includes the isolation structure 130. The isolation structure 130 is flush with the top surface of the substrate 100, where the top surface refers to a surface for performing the image sensor production process described herein on the substrate 100. In this application, if not specified, “surface” “on . . . ” refers to the side of the next step of the production process. The image sensor also includes a protective layer 101 formed on the surface of the substrate 100 and isolation structure 130; a photoelectric-doped region 102 formed in the substrate 100. The photoelectric-doped region 102 includes a kind of second dopant ions, and the conductivity type of the second dopant ions is opposite to that of the first dopant ions. The image sensor also includes an isolation region 103, where the isolation region 103 isolates the protective layer 101 and the photoelectric-doped region 102, as well as the isolation structure 130 and the substrate 100. The isolation region 103 includes a kind of third dopant ions, wherein the conductivity type of the third doped ions is opposite to that of the second doped ions. As shown in FIG. 1, the sensor further includes: a gate structure 104 formed on the protective layer 101 after the isolation region 103 is formed, and the photoelectric-doped region 102 is located on one side of the gate structure 104; and a floating diffusion region 105 formed in the substrate 100 on the other side of the gate structure 104.

When the image sensor structure shown in FIG. 1 does not include the isolation region 103, the dark current is easy to occur at the interface between the surface of the substrate 100 and the protective layer 101. This is because: the material of the substrate 100 is silicon, silicon lattice is abruptly terminated on the surface of the substrate 100 such that a large number of dangling bonds are present at the interface between the surface of the substrate 100 and the protective layer 101. When the substrate 100 is heated, a strong dark current will be generated at the interface of the surface of the substrate 100 and the protective layer 101.

In the image sensor shown in FIG. 1, the isolation region 103 isolates the protective layer 101 and the photoelectric-doped region 102, as well as the isolation structure 130 and the substrate 100. Also, the conductivity type of the third dopant ions in the isolation region 103 is opposite to that of the second dopant ions. Therefore, the isolation region 103 may reduce dark current at the interface between the surface of the substrate 100 (corresponds to the portion of photoelectric-doped region 102) and the protective layer 101. However, the ability of the isolation region 103 to reduce the dark current at the interface between the surface of the substrate 100 (corresponds to the portion of photoelectric-doped region 102) and the protective layer 101 is not sufficient, so that the dark current at the interface between the surface of the substrate 100 (corresponds to the portion of photoelectric-doped region 102) and the protective layer 101 remains serious.

In order to solve the technical problem, the present disclosure provides a method of forming an image sensor, including providing a substrate, wherein the substrate includes a photoelectric region and a protective layer over a surface of the substrate; forming a photoelectric-doped region in the photoelectric region; and doping improvement ions at an interface between the photoelectric region of the substrate and the protective layer, wherein, the improvement ions are combined with a dangling bond at the interface. The method may reduce the dark current of the image sensor.

The above described objects, features and advantages of the present disclosure will become easier to understand by following detailed description of the embodiments with reference to accompanying drawings.

FIG. 2 to FIG. 11 are structural diagrams showing the steps of a method for forming an image sensor according to embodiments of the present disclosure.

Referring to FIG. 2, a substrate 200 is provided. The substrate 200 includes a photo-electric region A; a protective layer 280 is formed on the surface of the substrate 200; after the protective layer 280 is formed, a photoelectric-doped region 201 is formed in the photo-electric region A.

In some embodiments of the present disclosure, the material of the substrate 200 is silicon (Si).

The material of the substrate may also include, but not limited to, germanium (Ge), silicon germanium (GeSi), silicon carbide (SiC), silicon-on-insulator (SOD, germanium on insulator (GOI), gallium arsenide or III-V compound.

The formation process of the photoelectric-doped region 201 includes a second ion implantation process, the protective layer 280 is formed to protect the top surface of the substrate 200 during the second ion implantation process.

The substrate 200 includes a well region and a photoelectric-doped region. The well region (not shown in the figure) includes the first dopant ions therein, and the photoelectric-doped region 201 includes the second dopant ions therein. Further, the conductivity type of the second dopant ions is opposite to that of the first dopant ions, and thus, the photoelectric-doped region 201 forms a photodiode with the well region, and the photodiode is formed to absorb photons to generate electrons.

In some embodiments of the present disclosure, the image sensor includes pixels with at least one pixel structure. The pixel structure of the image sensor is of the N type, the first doped ions are P-type ions, and the second dopant ions are N-type ions. Alternatively, the pixel structure of the image sensor may also be of the P type. Accordingly, the first dopant ions are N-type ions, and the second dopant ions are P-type ions. The N-type ions include: any one or a combination of phosphorus ions, arsenic ions, and strontium ions; the P-type ions include any one or a combination of boron ions, gallium ions, and indium ions.

The material of the protective layer 280 includes silicon oxide, and the forming process of the protective layer 280 includes a chemical vapor deposition process or a physical vapor deposition process.

When the photoelectric-doped region 201, the isolation region 260, and the floating diffusion region are subsequently formed on the substrate 200, the protective layer 280 is formed to protect the surface of the substrate 200, to prevent defects on the surface of the substrate 200, and to improve the performance of the image sensor.

The substrate 200 may further include an isolation structure 250. The method for forming the isolation structure 250 includes: forming a first mask layer (not shown in the figure) on the surface of the substrate 200, the first mask layer being exposed a top surface of a portion of the substrate 200; etching the substrate 200 with the first mask layer as a mask, forming an isolation opening in the substrate 200; forming an isolation material film in the isolation opening and on the surface of the substrate 200, the isolation material film fills the isolation opening; flattening the isolation material film until the top surface of the substrate 200 is exposed, forming an isolation structure 250 within the isolation opening.

The material of the first mask layer includes silicon nitride, titanium nitride, or any combination thereof. The first mask layer is formed to define the size and location of the isolation opening.

The process of etching the substrate 200 using the first mask layer as a mask includes one or any combination of a dry etching process and a wet etching process.

The material of the isolation material film includes silicon oxide, silicon oxynitride or any combination thereof. The formation process of the isolation material film includes a chemical vapor deposition process or a physical vapor deposition process.

The process of flattening the separation material film includes a chemical mechanical polishing process.

The isolation structure 250 is formed to achieve electrical isolation between different devices.

According to FIG. 2, a doped isolation region 290 is formed between the isolation structure 250 and the substrate 200, wherein the conductivity type of the doped ions in the doped isolation region 290 is opposite to that of the doped ions in the photo-doped region 201. The doped isolation region 290 reduces the surface state density between the isolation structure 250 and the substrate 200. Reducing the surface states density may effectively reduce dark current.

The forming method may further include forming the isolation region 260 between the substrate 200 corresponding to the photoelectric region A and the protective layer 280, wherein the isolation region 260 includes a kind of fourth dopant ions, and the conductivity type the fourth dopant ions is opposite to that of the second doped ions in the photoelectric doping region 201.

In some embodiments of the present disclosure, the photoelectric-doped region 201 is N-type doped, and the isolation region 260 is P-type doped.

In FIG. 2, the thickness of the isolation region 260 is not drawn to scale for clarity. In the production process, in order not to affect the performance of the photodiode, the thickness of the isolation region 260 should be as thinner as possible.

The forming process of the isolation region 260 includes performing a first ion implantation process at a corresponding location in the substrate. It should be noted that since the ion doping type of the isolation region 260 is the same as that of the doped isolation region 290, the isolation region 260 and the doped isolation region 290 are represented by the same filling line. Those skilled in the art will appreciate that the isolation regions 260 and the doped isolation regions 290 are not formed in the same process step.

According to an aspect of the present disclosure, one of a significance of forming the isolation region 260 is that since the conductivity type of the fourth dopant ions in the isolation region 260 is opposite to that of the second dopant ions in the photo-doped region 201, the isolation region 260 is formed to reduce the surface state at the interface between the substrate 200 corresponding to the photoelectric region A and the protective layer 280, thereby reducing the dark current at the interface.

In some embodiments of the present disclosure, the isolation region 260 may or may not be required by proper designs of the image sensor. For example, the dark current of the image sensor may be reduced by merely doping improvement ions at the interface of the substrate 200 corresponding to the photo-electric region A and the protective layer 280, where the improvement ions are used to combine the dangling bond at the interface, details of the above design are shown in FIG. 3 to FIG. 9. Although the isolation regions 260 are schematically illustrated in FIGS. 3 to 9, it is not meant that the isolation regions 260 are present in each of the embodiments.

Referring to FIG. 3, the image sensor includes: a first gate structure 202 formed on the surface of the protective layer 280; a floating diffusion region 204 formed in the substrate 200 on the side of the first gate structure 202, and the floating diffusion region 204 and the photoelectric-doped regions 201 respectively located on both sides of the first gate structure 202; and a second gate structure 203 formed on the surface of the protective layer 280 corresponding to the portion of the photoelectric region A.

The first gate structure 202 is formed to transfer the resistance generated by the photodiode into the floating diffusion region 204.

In some embodiments of the present disclosure, the second gate structure 203 is formed to define a doping position of the subsequent improvement ions.

In some embodiments of the present disclosure, the first gate structure 202 and the second gate structure 203 are simultaneously formed. The forming method of the first gate structure 202 and the second gate structure 203 includes: forming a gate dielectric film on the surface of the protective layer 280; forming a gate film on the surface of the gate dielectric film, the gate film surface including a second mask layer (not shown in the figure), the second mask layer exposing the top surface of a portion of the gate film; etching the gate film and the gate dielectric film with the second mask layer as a mask until the top surface of the protective layer is exposed to form a first gate structure 202 and a second gate structure 203.

According to various embodiments of the present disclosure, either the second gate structure is formed after the first gate structure is formed; or the second gate structure is formed before the first gate structure is formed; or only the first gate structure is formed.

The side surfaces of the first gate structure 202 and the second gate structure 203 may also be covered by spacers. (not shown in the figure).

The material of the spacers includes silicon nitride or silicon oxynitride. The spacers are formed to protect side surfaces of the first gate structure 202 and the second gate structure 203.

The formation process of the floating diffusion region 204 includes a third ion implantation process, the protective layer 280 is formed to protect the top surface of the substrate during the third ion implantation process. The floating diffusion region 204 is formed to store electrons generated by a photodiode.

In some embodiments of the present disclosure, the third dopant ions are N-type ions, and the N-type ions include one or any combination of phosphorus ions, arsenic ions, and strontium ions.

Alternatively, the third dopant ions are P-type ions, and the P-type ions comprise one or any combination of boron ions, gallium ions, and indium ions.

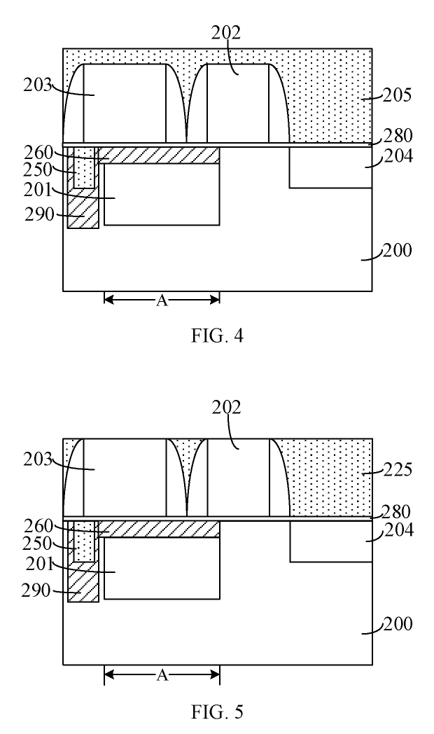

Referring to FIG. 4, the image sensor includes a first dielectric film 205 is formed on the side surface and the top surface of the first gate structure 202, the side surface and the top surface of the second gate structure 203, and the surface of the substrate 200.

The material of the first dielectric film 205 includes silicon oxide, silicon oxynitride, or any combinations thereof. The formation process of the first dielectric film 205 includes a chemical vapor deposition process or a physical vapor deposition process.

The first dielectric film 205 is formed to subsequently form a first dielectric layer.

Referring to FIG. 5, the first dielectric film 205 is flattened until the top surfaces of the first gate structure 202 and the second gate structure 203 are exposed to form a first dielectric layer 225.

The process of flattening the first dielectric film 205 includes a chemical mechanical polishing process.

Flattening the first dielectric film 205 to expose the top surface of the second gate structure 203 is advantageous to subsequent removal of the second gate structure 203.

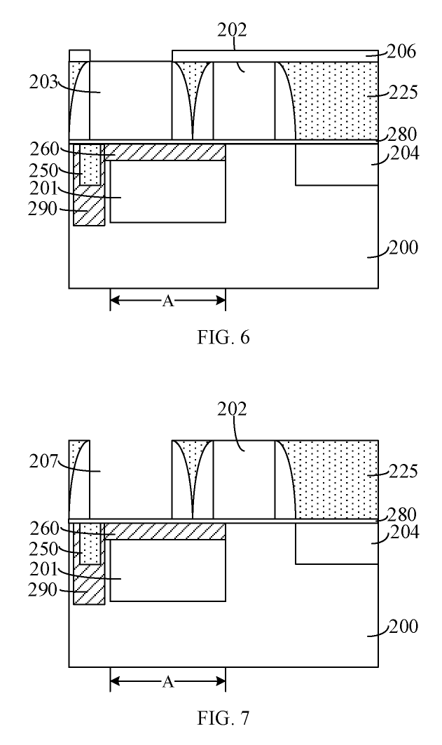

Referring to FIG. 6, a photoresist 206 is formed on the surface of the first dielectric layer 225, and the photoresist 206 exposes the top surface of the second gate structure 203.

In the subsequent removal of the second gate structure 203, the photoresist 206 is formed to protect the first gate structure from being removed.

Referring to FIG. 7, the second gate structure 203 is removed by using the photoresist 206 as a mask, and an opening 207 is formed in the first dielectric layer 225.

The process of removing the second gate structure 203 includes one or any combination of a dry etching process and a wet etching process.

The opening 207 is formed to subsequently form the improvement layer and the second dielectric layer on top of the improvement layer.

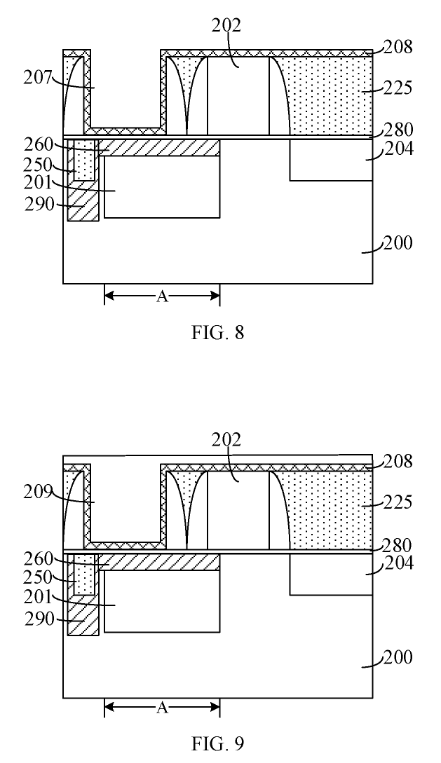

Referring to FIG. 8, an improvement layer 208 is formed on the bottom surface of the opening 207. The improvement layer 208 includes improvement ions, the improvement ions diffuse to the interface of the substrate 200 corresponding to photoelectric region A and the protective layer 280 (when the isolation region 260 presents, the interface refers to a interface between isolation 260 and protective layer 280), and combined with the SiO2-Si dangling bonds at the interface, improve the surface density, therefore reduce the dark current of the image sensor.

In some embodiments of the present disclosure, the improvement layer 208 also covers the sidewalls of the opening 207 and the top surface of the first dielectric layer 225. In other embodiments of the present disclosure, the improvement layer covers only the surface of the protective layer of the bottom of the opening.

The material of the improvement layer 208 includes: fluorine-doped silicon oxide, and the improvement ions include: fluoride ions.

Since the second gate structure 203 is not in contact with the first gate structure 202, the second gate structure 203 is formed to define the position of the improvement layer 208 such that the improvement layer 208 is not in contact with the first gate structure 202. Thus, the improvement ions within the improvement layer 208 do not affect the performance of the first gate structure 202.

At the same time, since the ionic radius of the improvement ions is small and the diffusion ability is strong, so that the improved ions may diffuse to the interface between the substrate 200 corresponding to photoelectric region A and the protective layer (when the isolation region 260 presents, the interface refers to a interface between isolation 260 and protective layer 280), while subsequently performing the anneal. the improvement ions may be combined with the dangling bonds at the interface, therefore, the improvement ions can repair the defects at the interface, and therefore, it is advantageous to reduce the dark current at the interface between the substrate 200 corresponding to photoelectric region A and the protective layer 280 (when the isolation region 260 presents, the interface refers to a interface between isolation 260 and protective layer 280), and improve the performance of the image sensor.

In summary, the improvement layer and improvement ions may reduce the dark current at the interface between the substrate 200 corresponding to photoelectric region A and the protective layer 280 (when the isolation region 260 presents, the interface refers to a interface between isolation 260 and protective layer 280)while not affecting the performance of the first gate structure 202, and the process is simple.

The doping concentration (atomic percentage concentration) of the improvement ions in the improvement layer 208 is: 1% to 10%, and the significance of selecting the doping concentration of improvement ions in the improvement layer 208 is: if the doping concentration of the improvement ions in the improvement layer 208 is less than 1%, so that the ability of the improvement layer 208 to improve the dark current is weak, the dark current of the image sensor is still serious, and the performance of the image sensor is still poor; if the doping concentration of the improvement ions in the improvement layer 208 is greater than 10%, doping is more difficult. In some embodiment of the present disclosure, the atomic percentage concentration of the improvement ions in the improvement layer 208 is, for example, 3%, 5% or 8%.

Referring to FIG. 9, a second dielectric film 209 is formed on the surface of the improvement layer 208, and the second dielectric film 209 fills the opening 207.

The material of the second dielectric film 209 includes silicon oxide or silicon oxynitride, and the formation process of the second dielectric film 209 includes a chemical vapor deposition process or a physical vapor deposition process.

The second dielectric film 209 is formed to subsequently form a second dielectric layer.

In some embodiments of the present disclosure, after the second dielectric film 209 is formed, an anneal is performed. Alternatively, after the second dielectric film is formed, the annealing treatment is not performed.

During the annealing process, the improvement ions enter the interface of the substrate 200 corresponding to photoelectric region A and the protective layer 280 (when the isolation region 260 presents, the interface refers to a interface between isolation 260 and protective layer 280) to repair defects, and thus, it is advantageous to reduce the dark current at the interface between the substrate 200 corresponding to photoelectric region A and the protective layer 280.

The annealing process includes a rapid annealing process, and the parameters of the rapid annealing process include: an annealing temperature of 400 degrees Celsius to 700 degrees Celsius, and an annealing time of 30 seconds to 120 seconds.

According to an aspect of the present disclosure, one of a significance of selecting the annealing temperature is that if the annealing temperature is less than 400 degrees Celsius, it is difficult for the improvement ions to diffuse to the interface between the substrate 200 corresponding to photoelectric region A and the protective layer 280 (when the isolation region 260 presents, the interface refers to a interface between isolation 260 and protective layer 280) such that the dark current at the interface is still serious; if the annealing temperature is greater than 700 degrees Celsius, so that the diffusion rate of improvement ions is too fast, it is difficult to control the improvement ions.

According to some embodiments of the present disclosure, the second gate structure is not formed, only the first gate structure is formed, and dopant ions are doped at the interface between substrate of the substrate corresponding to the photoelectric region A and the protective layer 280 (when the isolation region 260 presents, the interface refers to a interface between isolation 260 and protective layer 280) before the first gate structure is formed. For example, the method of doping dopant ions at the interface includes: forming an improvement layer on the surface of a portion of substrate of the photo-electric region, wherein the improvement layer includes improvement ions, and performing an annealing treatment to make the improvement ions enter the interface of substrate corresponding to the photoelectric region and the protective layer 280 (when the isolation region 260 presents, the interface refers to a interface between isolation 260 and protective layer 280).

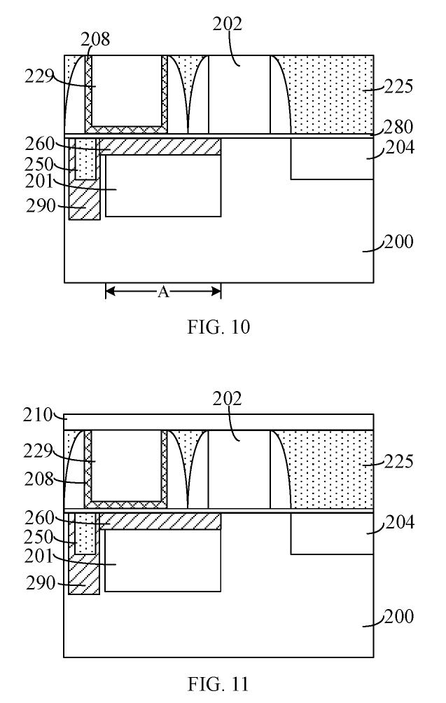

Referring to FIG. 10, the second dielectric film 209 is flattened until the top surface of the first gate structure 202 is exposed, and a second dielectric layer 229 is formed in the opening 207 (see FIG. 7).

The process of flattening the second dielectric film 209 includes a chemical mechanical polishing process.

Referring to FIG. 11, a third dielectric layer 210 is formed on the surface of the second dielectric layer 229.

The material of the third dielectric layer 210 includes silicon oxide or silicon oxynitride, and the formation process of the third dielectric layer 210 includes a chemical vapor deposition process or a physical vapor deposition process.

in some embodiments of the present disclosure, after forming the third dielectric layer, an annealing process may be further included to repair the lattice structure of the second dielectric layer 229 and the third dielectric layer 210

Correspondingly, the present disclosure also provides an image sensor, referring to FIG. 8, includes:

a substrate 200 including a protective layer 280 on the surface thereof, the substrate 200 includes a photo-electric region A; a photoelectric-doped region 201 located in substrate 200 corresponding to the photo-electric region A; improvement ions at the interface between substrate 200 corresponding to the photoelectric region A and the protective layer 280, the improvement ions are combined with the dangling bonds at the interface.

The improvement ions include fluoride ions.

The photoelectric-doped region 201 includes second dopant ions therein; the substrate 200 may further include a well region, the well region includes a kind of first dopant ions, and the conductivity type of the first dopant ions is opposite to that of the second dopant ions

The substrate 200 may further include an isolation structure 250 therein; the image sensor further includes: an isolation region 260 surrounding the isolation structure 250 and the top of the photoelectric-doped region 201, wherein the isolation region 260 includes a kind of fourth dopant ions therein, the conductivity type of the fourth dopant ions is opposite to that of the second dopant ions.

The image sensor may further include an improvement layer 208 on the corresponding protective layer 280 of the photo-electric region A, the improvement layer 208 including the improvement ions. The material of the improvement layer includes: fluorine-doped silicon oxide, and the improvement ions include: fluoride ions.

An isolation region 260 may be further included between the photoelectric-doped region 201 and the protective layer 280, and the conductivity type of the dopant ions in the isolation region 260 is opposite to the that of the dopant ions in the photoelectric-doped region 201. The substrate 200 includes an isolation structure 250 and a doped isolation region 290. The doped isolation region 290 is located between the isolation structure 250 and the substrate 200. The conductivity type of the dopant ions in the doped isolation region is opposite to that of the dopant ions in the photoelectric-doping region.

Although the present disclosure has been disclosed above, the present disclosure is not limited thereto. Those skilled in the art may make any changes and modifications without departing from the spirit and scope of the disclosure, so that the scope of the disclosure should be determined by the scope defined by the claims.

What is claimed is what is claimed is:

1. A method for forming an image sensor, comprising:
providing a substrate including: a protective layer over a surface of the substrate, and a photoelectric region;
forming a photo-doped region in the photoelectric region; and
doping improvement ions at an interface between the photoelectric region of the substrate and the protective layer, wherein the improvement ions are combined with a dangling bond at the interface.

2. The method as claimed in claim 1, wherein the improvement ions include fluoride ions.

3. The method as claimed in claim 1, wherein the doping of the improvement ions at the interface includes:
forming an improvement layer on the corresponding protective layer of the photoelectric region, wherein the improvement layer includes the improvement ions; and
performing anneal to diffuse the improvement ions to the interface between the protective layer and the photoelectric region.

4. The method as claimed in claim 3, wherein the method of doping the improvement ions at the interface includes:
forming a second gate structure on a surface of a portion of the photoelectric region;
forming a first dielectric layer over the second gate structure, wherein a thickness of the first dielectric layer substantially equals to that of the gate structure;
removing the second gate structure to form an opening in the first dielectric layer, the opening exposing the protective layer;
forming the improvement layer at the bottom of the opening, the improvement layer including the improvement ions; and
performing the anneal to diffuse the improvement ions to the interface.

5. The method as claimed in claim 3, wherein a material of the improvement layer includes fluorine-doped silicon oxide, and the improvement ions include fluoride ions.

6. The method as claimed in claim 3, wherein the forming of the improvement layer includes performing a solid source doping process.

7. The method as claimed in claim 3, wherein an atomic percentage concentration of the improvement ions in the improvement layer is 1% or more and 10% or less.

8. The method as claimed in claim 3, wherein the anneal includes a rapid anneal having an annealing temperature of 400 degrees Celsius or more and 700 degrees Celsius or less, and an annealing time of 30 seconds or more and 120 seconds or less.

9. The method as claimed in claim 4, further comprising, before forming the first dielectric layer:
forming a first gate structure on the surface of the substrate; and
forming a floating diffusion region in the substrate at one side of the first gate structure, wherein the floating diffusion region and the photo-doped region are respectively located on opposite sides of the first gate structure, and the floating diffusion region includes third dopant ions, wherein the third dopant ions are of a same doping type as second dopant ions, and the second dopant ions are located in the photo-doped region.

10. The method as claimed in claim 9, further comprising, after forming the improvement layer:
forming a second dielectric film in the opening and a surface of the first dielectric layer, the second dielectric film filling the opening; and
flattening the second dielectric film until a top surface of the first gate structure is exposed, and the second dielectric layer is formed within the opening.

11. The method as claimed in claim 10, wherein the anneal is performed after the second dielectric film is formed and before the second dielectric layer is formed.

12. The method as claimed in claim 1, further comprising: forming an isolation region between the photo-doped region and the protective layer, and
forming the isolation region by performing an ion implantation process on the substrate, wherein a conductivity type of dopant ions in the isolation region is opposite to that of dopant ions in the photo-doped region.

13. The method as claimed claim 1, wherein the substrate includes an isolation structure, and a doped isolation region between the isolation structure and the substrate, wherein the doping isolation region is formed by performing an ion implantation process on the substrate, and a conductivity type of dopant ions in the doped isolation region is opposite to that of dopant ions in the photo-doped region.

14. An image sensor, comprising:
a substrate including: a protective layer over a surface of the substrate, and a photoelectric region;
a photo-doped region located within the photoelectric region;
at least a layer of improvement ions located at an interface between the photoelectric region and the protective layer, wherein the improvement ions are combined with a dangling bond at the interface.

15. The image sensor as claimed in claim 14, wherein the improvement ions include fluoride ions.

16. The image sensor as claimed in claim 14, further comprising:
an improvement layer, located on a corresponding protective layer of the photoelectric region, wherein the improvement layer includes the improvement ions.

17. The image sensor as claimed in claim 16, wherein a material of the improvement layer includes fluorine-doped silicon oxide, and the improvement ions include fluoride ions.

18. The image sensor as claimed in claim 14, wherein the photo-doped region includes second dopant ions; and
the substrate further include a well region, including first dopant ions, wherein a conductivity type of the first dopant ions is opposite to that of the second dopant ions.

19. The image sensor as claimed in claim 14, further comprising an isolation region between the photo-doped region and the protective layer, wherein a conductivity type of dopant ions in the isolation region is opposite to that of dopant ions in the photo-doped region.

20. The image sensor as claimed in claim 14, wherein the substrate includes:
an isolation structure; and
a doped isolation region located between the isolation structure and the substrate, wherein a conductivity type of the dopant ions in the doped isolation region is opposite to that of dopant ions in the photo-doped region.
